(19) United States
(12) Patent Application Publication
(10) Pub. No.: US 2009/0155546 A1
(43) Pub. Date: Jun. 18, 2009

(54) FILM-FORMING COMPOSITION, METHOD FOR PATTERN FORMATION, AND THREE-DIMENSIONAL MOLD

(75) Inventors: Naoki Yamashita, Kanagawa (JP); Kiyoshi Ishikawa, Kanagawa (JP); Yoshinori Sakamoto, Kanagawa (JP); Takuma Hojo, Kanagawa (JP)

Correspondence Address: HOFFMANN & BARON, LLP, 6900 JERICHO TURNPIKE, SYOSSET, NY, 11791, US

(73) Assignee: TOKYO OHKA KOGYO CO., LTD., Kanagawa (JP)

(21) Appl. No.: 12/064,342

(22) PCT Filed: Aug. 28, 2006
(86) PCT No.: PCT/JP2006/316881

§ 371 Date: Feb. 21, 2008

(30) Foreign Application Priority Data
Aug. 29, 2005 (JP) 2005-248353

(51) Int. Cl. B32B 5/00; G03F 7/20; G03F 7/004

(52) U.S. Cl. 428/195.1; 430/325; 430/270.1

(57) ABSTRACT

Disclosed are a film-forming composition which can form a pattern having an enhanced contrast by the action of uneven surface morphology produced after image development, and a method for forming a pattern and a three-dimensional mold using the composition. A composition comprising at least one of a hydrolysate and a condensation product of an alkoxy metal compound represented by the chemical formula (A), the composition additionally comprising a compound which can respond to at least one of light and heat to control the solubility of a finished film in a developing solution.

R¹ₙ-M(OR²)₄₋ₙ (A)

wherein M represents a silicon, a germanium, a titanium, a tantalum, an indium or a tin; R¹ represents a hydrogen atom or a monovalent organic group; R² represents a monovalent organic group; and n represents an integer of 1 to 3.

### TECHNICAL FIELD

The present invention relates to a film forming composition, a pattern formation method and a three-dimensional mold using the composition. Particularly, the present invention relates to a film forming composition in which the contrast between lands and grooves formed on a film following image development can be enhanced as a result of controlling the solubility of a formed film in a developing solution by responding to at least one of light and heat, and a pattern formation method and a three-dimensional mold using the composition.

### BACKGROUND ART

Lithography techniques have been used as a core technology in semiconductor device processes, and with recent advancement in highly integrated semiconductor integrated circuits (IC), exceedingly finer wiring patterns have been formed. In semiconductor integrated circuits (IC) referred to as very-large-scale integrated circuits having a degree of element integration of no less than 10,000,000 elements, use of micro processing lithography technology is indispensable.

To date, producing very-large-scale integrated circuits using micro processing lithography technology has employed techniques such as photolithography using KrF laser, ArF laser, F₂ laser, X-ray, or far-ultraviolet light. Recently, by using such photolithography technology, pattern formation having a line width as small as several tens of nm has become possible.

However, with the further achievement of finer patterns in photolithography technology, the initial costs of exposure devices have increased in relation to such devices that were originally expensive. Also, in the photolithography, a mask having high definition equivalent to that of the wavelength of light is necessary, and such a mask having a fine pattern has been very expensive. Furthermore, the demand for high integration has remained, and increasingly finer patterns have been desired.

Under these circumstances, nanoimprint lithography was proposed in 1995 by Chou et al. of Princeton University (Patent Document 1). Nanoimprint lithography is a technology which transfers the pattern of a mold to a resist by pressing the mold having a predetermined circuit pattern, onto the surface of a substrate on which the resist has been applied.

With respect to the nanoimprint lithography proposed by Chou et al., a pattern is formed by transferring the nano-scale shape of lands and grooves provided in the mold to the resist film. As a result, the time required for pattern formation can be reduced, and throughput is improved, thereby enabling mass production of the resist pattern.

Patent Document 1: U.S. Pat. No. 5,772,905

### DISCLOSURE OF THE INVENTION

### Problems to be Solved by the Invention

In imprint lithography, as previously described, the precision of molds that are used matters, because the contrast itself formed between lands and grooves of the mold pattern in the mold is transferred as a resist pattern in imprint lithography. Especially, in this process, to attain nano-scale imprint lithography, a mold having a micro three-dimensional shape is required.

However, producing a three-dimensional mold for use in imprint lithography had been difficult since advanced processing techniques were necessary. Especially, in the production of a mold having a three-dimensional structure of high contrast, highly advanced technology has been required. In particular, attaining a three-dimensional mold having nano-scale shape of lands and grooves, required at the time, was extremely difficult.

The present invention was made in view of the above problems, and an object of the present invention is to provide a film forming composition which can achieve a three-dimensional pattern in which the contrast between lands and grooves formed on a film following image development is enhanced, and a pattern formation method and a three-dimensional mold using the composition.

### Means for Solving the Problems

In order to solve the abovementioned problems, the present inventors have conducted thorough experimentation, and focused their attention on the need for controlling the solubility of film formed from the film forming composition in the developing solution. As a result, the present invention was accomplished in light of possibility of resolving the abovementioned problems, by formulating with a film forming composition a compound which can control the solubility of formed film in the developing solution by responding to at least one of light and heat. More specifically, the present invention provides the following.

A first aspect of the present invention relates to a film forming composition including at least one of a hydrolyzate and a condensate of an alkoxy metal compound represented by the following formula (A), and a contrast enhancer which enhances the contrast between lands and grooves formed on a film following image development as a result of controlling the solubility of the formed film in a developing solution by responding to at least one of light and heat.

R¹ₙ-M(OR²)₄₋ₙ (A)

wherein,

M represents silicon, germanium, titanium, tantalum, indium or stannum;

R¹ represents a hydrogen atom or a monovalent organic group;

R² represents a monovalent organic group; and

n is an integer of 1 to 3.

The film forming composition according to the first aspect is a composition having a function to enhance the contrast between lands and grooves formed on a film following image development as a result of controlling the solubility of the formed film in a developing solution by responding to at least one of light and heat. The contrast enhancer of the present invention responds to at least one of light and heat, and may either increase or decrease the solubility of the formed film in the developing solution.

In cases where the contrast enhancer increases the solubility of the formed film in the developing solution by responding to at least one of light and heat, the composition of the present invention becomes a positive type film forming composition. On the other hand, in cases where the contrast enhancer deareases the solubility of the formed film in the developing solution, the composition of the present invention becomes a negative film forming composition.

According to the film forming composition of the first aspect, following film formation, partial exposure thereto of light or heat causes a difference in the solubility in the developing solution between the region where the light or heat has been applied and the remaining region. Thus, following subsequent development step, a pattern having a three-dimensional structure with enhanced contrast of lands and grooves can be obtained with precision.

A second aspect of the film forming composition according to the first aspect of the present invention is a composition in which the content of the contrast enhancer is no less than 0.1% by mass and no greater than 30.0% by mass of the total mass of the film forming composition.

The content of the contrast enhancer in the film forming composition according to the second aspect is no less than 0.1% by mass and no greater than 30.0% by mass. The effect of the contrast enhancer can be sufficiently obtained by formulating the contrast enhancer in an amount of no less than 0.1% by mass, thus a pattern having sufficient contrast can be provided following treatment in the developing solution. On the other hand, retention stability of the film forming composition can be improved by formulating to include no greater than 30.0% by mass of the contrast enhancer, and the fall of the film decrement in the unexposed section during image developing can be prevented, whereby deterioration of the contrast can be prevented. The content of the contrast enhancer in the film forming composition is preferably no less than 1.0% by mass and no greater than 15.0% by mass, and more preferably no less than 5.0% by mass and no greater than 10.0% by mass.

In a third aspect of the film forming composition according to the first or second aspect of the present invention, the contrast enhancer is a photobase generator.

The film forming composition according to the third aspect uses a photobase generator as the contrast enhancer. The photobase generator is a compound which generates a base in response to light. When subjecting a coating film obtained from the film forming composition of the present invention to an image development process, it is likely that acid is frequently used as a developing solution. Therefore, when a base is generated from the photobase generator upon exposure to light, the base included in the coating film reacts with the acid included in the developing solution to enable further improvement of the solubility of the irradiated region.

A fourth aspect of the film forming composition according to any one of the first to third aspects of the present invention is used for forming a three-dimensional mold.

The film forming composition of the fourth aspect is used for forming a three-dimensional mold. The three-dimensional mold is a mold having lands and grooves on the surface, and, for example, it can be used in imprint lithography. According to the film forming composition of the present invention, the mold with enhanced contrast can be obtained with the presence of the contrast enhancer.

In a fifth aspect of the present invention, a three-dimensional mold is obtained by exposing light to a coating film obtained from the film forming composition according to any one of the first to fourth aspects of the present invention, followed by image development.

The three-dimensional mold according to the fifth aspect is obtained by exposing light to the coating film obtained from the film forming composition of the present invention, and conducting image development thereafter. The film forming composition of the present invention responds to at least one of light and heat, thereby causing a difference in solubility between responded and non-responded regions thereof in a developing solution. Thus, exposing a particular region of the film forming composition of the present invention to light, followed by image development, results in a three-dimensional mold of a desired shape.

In a sixth aspect of the present invention, the three-dimensional mold according to the fifth aspect, further includes step-shaped lands and grooves constructed with a plurality of combined lands and grooves obtained by performing sequential exposure of irradiation at a controlled intensity.

The three-dimensional mold according to the sixth aspect includes step-shaped lands and grooves constructed with a plurality of combined lands and grooves (hereinafter simply referred to as the “step-shaped lands and grooves”), obtained by performing exposure of irradiation multiple times at different intensities, and by image development thereafter. The film forming composition of the present invention responds to at least one of light and heat, thereby controlling the solubility of a responded region in the developing solution. Accordingly, response depth in a thickness direction of the coating film constituted with the film forming composition can be controlled not only by varying the region irradiated with light or heat but also by varying the intensity of irradiation. Thus, exposure of light having an irradiation intensity sufficient to influence up to a deepest portion of the coating film in the thickness direction, and exposure of light having an irradiation intensity that is not sufficient to influence up to the deepest portion of the coating film in a thickness direction of the coating film (for example, irradiation intensity that only influences up to the mid part of the coating film in the thickness direction) are sequentially performed, and image development thereafter, enables the formation of the three-dimensional mold having step-shaped lands and grooves.

The three-dimensional mold having step-shaped lands and grooves according to the sixth aspect, enables the formation of a pattern having step-shaped lands and grooves (step-shape) by performing a single transfer.

In a seventh aspect of the present invention, use of the three-dimensional mold according to the fifth or sixth aspect in lithography is provided.

The three-dimensional mold is an important element in lithography technology. Especially, transfer patterns obtained in imprint lithography are greatly affected by the degree of precision in the contrast of the three-dimensional mold. The degree of precision in the contrast of the three-dimensional mold according to the fifth or sixth aspect of the present invention, having formed lands and grooves or step-shaped lands and grooves thereon, is sufficiently high. As a consequence, a transfer pattern having higher precision can be obtained even when used for lithography.

Also, in imprint lithography, resist films are deformed when pressure is applied to the corresponding molds, thus, the degree of hardness of a mold being employed is required to be greater than that of the resist layer being applied to a substrate. The three-dimensional mold according to the fifth or sixth aspect has a degree of hardness that can withstand use as a mold for imprint lithography.

Furthermore, the three-dimensional mold according to the fifth or sixth aspect is light transparent. Therefore, in imprint lithography, a resist film can be cured by irradiation of light such as ultraviolet light that has passed through a mold, while maintaining a state of pressing the mold onto the resist film.

In an eighth aspect of the present invention, a pattern formation method using lithography is provided, including a coating step for obtaining a coating layer by applying the film forming composition of any one of the first to third aspects of the present invention, a first baking step for forming a cured film by baking or partially baking the coating layer, an exposure step for obtaining an exposed film in at least a portion of the cured film exposed to light as an exposed area, and a developing step for treating the exposed film in a developing solution and selectively dissolving either the exposed area or a non-exposed area other than the exposed area.

The pattern formation method according to the eighth aspect is a method for forming a pattern via coating step, first baking step, exposure step, and developing step using the film forming composition of the present invention. The film forming composition of the present invention responds to at least one of light and heat, thereby controlling the solubility of responded region in a developing solution. Because of this, either the exposed area or the non-exposed area can be selectively dissolved in a developing solution, enabling the formation of a pattern having high contrast.

In a ninth aspect of the present invention, the pattern formation method according to the eighth aspect further includes a second baking step for baking the exposed film after the exposure step.

The pattern formation method according to the ninth aspect includes second baking step after the exposure step. If the second baking step is carried out after the exposure step, the degree of hardness of the pattern to be provided thereafter can be improved. Thus, a pattern provided by the pattern formation method according to the ninth aspect can sufficiently withstand use which requires a certain degree of hardness.

In a tenth aspect of the present invention, the exposure step of the pattern formation method according to the eighth or ninth aspect is electron beam lithography.

The pattern formation method according to the tenth aspect performs an exposure step by electron beam lithography. In electron beam lithography, irradiation can be performed while specifying a fine range, and by varying the irradiation intensity, control of response depth of the film forming composition in the thickness direction becomes possible. Thus, according to the pattern formation method of the tenth aspect, a pattern having a structure of fine lands and grooves can be obtained.

In an eleventh aspect of the present invention, the developing solution of the pattern formation method according to any one of the eighth to tenth aspects is a buffered hydrofluoric acid.

The pattern formation method according to the eleventh aspect uses a buffered hydrofluoric acid (BHF) as a developing solution. The buffered hydrofluoric acid (BHF) is a solution which includes hydrofluoric acid and ammonium fluoride in combination. There are cases where the coating film constituted with the film forming composition of the present invention becomes glassy when the first baking step is carried out. The buffered hydrofluoric acid (BHF) is effective in corroding glassy material. Because of this, in the pattern formation method according to the eleventh aspect, buffered hydrofluoric acid is used as the developing solution.

In a twelfth aspect of the present invention, the pattern formation method according to any one of the eighth to eleventh aspects is a nano-pattern formation method.

The pattern formation method according to the twelfth aspect is a method for forming a nano-scale pattern. According to the film forming composition of the present invention, contrast of the resulting three-dimensional pattern is enhanced. Because of this, a nano-scale pattern can be formed by finely controlling the irradiation region and irradiation intensity in the exposure step.

A thirteenth aspect of the present invention is a three-dimensional structural body obtained by the pattern formation method according to any one of the eighth to twelfth aspects.

The film forming composition of the present invention responds to at least one of light and heat, and creates a solubility difference between a responded region and a non-responded region, when in a developing solution. In the three-dimensional structural body of the thirteenth aspect, a desirable three-dimensional shape can be formed by subjecting a particular region to exposure of light in the exposure step, and performing the development step thereafter.

In a fourteenth aspect of the present invention, the three-dimensional structural body according to the thirteenth aspect includes step-shaped lands and grooves formed by combining a plurality of lands and grooves.

The film forming composition of the present invention responds to at least one of light and heat, thereby controlling the solubility of the responded region in developing solution. As a consequence, not only by varying the region of irradiation of light or heat, but also by varying the irradiation intensity, a depth sufficient to influence the coating film formed from the film forming composition can be controlled.

The three-dimensional structural body according to the fourteenth aspect includes step-shaped lands and grooves constructed with a combination of a plurality of lands and grooves can be obtained by sequentially performing exposure to the three-dimensional structural body of light having an irradiation intensity sufficient to influence up to a deepest portion of the coating film in the thickness direction, and exposure of light having an irradiation intensity that is not sufficient to influence up to the deepest portion of the coating film in a thickness direction of the coating film (for example, irradiation intensity that only influences up to the mid part of the coating film in the thickness direction), and performing a development step thereafter.

In a fifteenth aspect of the present invention, the three-dimensional structural body according to the thirteenth or fourteenth aspect is a nano-structural body.

According to the film forming composition of the present invention, contrast of obtained pattern is enhanced. The nano-structural body according to the fifteenth aspect can form a nano-scale structure by a pattern formation method in which at least one of the exposed area and irradiation intensity is finely controlled in the exposure step, and a development step is thereafter performed.

In a sixteenth aspect of the present invention, the three-dimensional structural body according to any one of the thirteenth to fifteenth aspects is a mold for lithography.

The three-dimensional structural body according to the thirteenth to fifteenth aspects includes lands and grooves or step-shaped lands and grooves with a sufficiently high degree of precision in the contrast. As a result, a transfer pattern having good precision is obtainable when it is used as a mold for lithography. Especially when using the three-dimensional structural body having step-shaped lands and grooves according to the fourteenth aspect as a mold for lithography, a pattern having the step-shaped lands and grooves can be obtained by a single transfer.

Also, even if the three-dimensional structural body according to the thirteenth to fifteenth aspects is used as a mold for imprint lithography, there is a degree of hardness sufficient to withstand use.

Furthermore, the three-dimensional structural body according to the thirteenth to fifteenth aspects is light transparent. As a result, when the three-dimensional mold is used as a mold for imprint lithography, the resist film can be cured by irradiation of light, such as ultraviolet light, which passes through the three-dimensional structural body, while maintaining a state of pressing the three-dimensional structural body against the resist film.

In a seventeenth aspect of the present invention, the three-dimensional structural body according to any one of the thirteenth to fifteenth aspects is a mold for nanoimprint lithography.

A three-dimensional structural body according to any one of the thirteenth to fifteenth aspects can be a structural body having a nano-scale structure by finely controlling at least one of the exposed area and intensity of irradiation in the exposure step, followed by the development step. The three-dimensional structural body having the nano-scale structure can be used satisfactorily as a mold for nanoimprint lithography.

### EFFECTS OF THE INVENTION

According to the film forming composition of the present invention, a film having enhanced contrast can be obtained by lands and grooves after development. Thus, a three-dimensional mold for use in imprint lithography having a fine three-dimensional structure can be obtained by using the film forming composition of the present invention.

Also, with respect to a mold for use in imprint lithography, it is necessary that the degree of hardness be higher than that of the resist layer applied to a substrate since a pressure applied to the mold must deform the resist film. The three-dimensional mold obtained from the film forming composition of the present invention has a degree of hardness sufficient to withstand use as a mold for imprint lithography.

Furthermore, the three-dimensional mold obtained from the film forming composition of the present invention is light transparent. As a result, in imprint lithography, the resist film can be cured by irradiating light, such as ultraviolet light, which passes through the mold, while maintaining a state of pressing the mold onto the resist film.

### BRIEF DESCRIPTION OF THE DRAWINGS

FIG. 1 shows a diagram illustrating steps of a pattern formation method by lithography;

FIG. 2 shows a diagram illustrating steps of a pattern formation method providing step-shaped lands and grooves.

### PREFERRED MODE FOR CARRYING OUT THE INVENTION

Embodiments of the present invention will hereinafter be described with reference to the attached drawings.

### First Embodiment

### Pattern Formation by Lithography

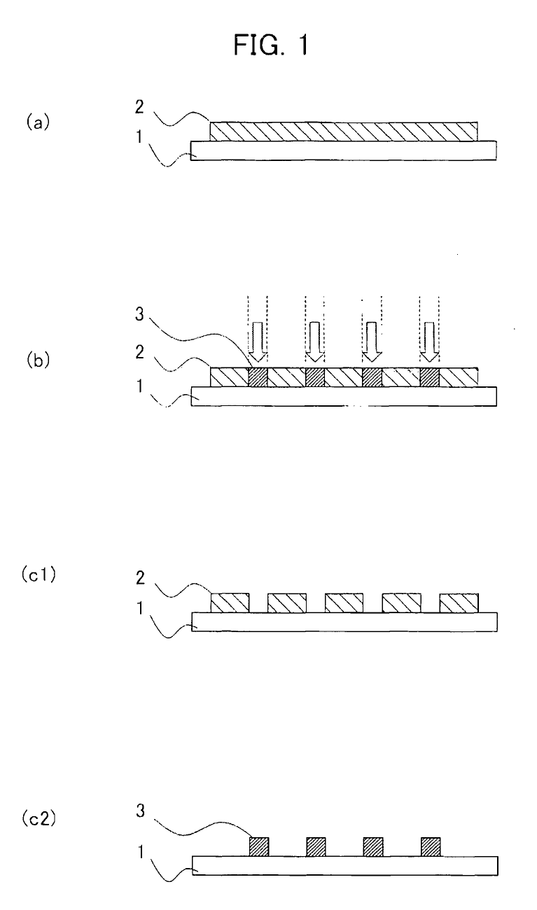

FIG. 1 shows a diagram illustrating steps of a pattern formation method according to a first embodiment of the present invention. In the first embodiment, a coating step (FIG. 1(a)), a first baking step (not shown in the Figure), an exposure step (FIG. 1(b)), a second baking step (not shown in the Figure), and a developing step (FIG. 1(c1), FIG. 1(C2)) are involved. Hereinafter, each step will be explained.

### [Coating Step]

FIG. 1(a) shows a diagram illustrating a coating step in the pattern formation method according to the first embodiment of the present invention. In the coating step, the film forming composition 2 of the present invention is applied on a substrate 1, thereby obtaining a coating layer of the film forming composition 2. Examples of the method for coating include, e.g., a spray coating method, a roll coating method, a spin-coating method, and the like.

The material of the substrate for use in the present invention is not particularly limited. It can be properly selected to suit their applications as the structural body obtained in the present invention. For example, when the obtained structural body is used as a mold for imprint lithography, as a material, for example, glass, polysilicon, polycarbonate, polyester, aromatic polyamide, polyamide-imide, polyimide, or the like is preferable since the obtained structural body is required to withstand the applied pressure. Furthermore, upon performing lithography by the photoimprint, due to irradiation of light (for example, UV etc.), it is preferable that the substrate has transparency, and particularly quartz is preferable.

### [First Baking Step]

The first baking step is a step to form a cured film of the film forming composition 2, by baking or partially baking the coating layer of the film forming composition 2 formed on the substrate 1 in the coating step.

The baking or partially baking conditions are not particularly limited. For example, the conditions in this process may be set at a temperature of no less than 100° C. and no greater than 400° C. for a time period of 60 seconds to 300 seconds, and particularly preferably, at a temperature of no less than 200° C. and no greater than 300° C. for a time period of 60 seconds to 180 seconds.

### [Exposure Step]

FIG. 1(b) shows a diagram illustrating the exposure step in the pattern formation method according to the first embodiment of the present invention. The exposure step is a step in which a cured film of the film forming composition 2 obtained through baking or partially baking in the first baking step, is exposed (shown in the diagram by an arrow) at least in part to give an exposed film having an exposed area 3.

A solubility difference in developing solution is generated between the exposed area 3 and the non-exposed area 2 due to the film forming composition 2 which responds to exposed light. When the solubility in the developing solution is increased by responding to the exposure, the exposed area 3 is removed by dissolving in the following development step. In contrast, when the solubility in the developing solution decreases due to a response to the exposure, the non-exposed area 2 is removed by dissolving in the following development step.

The exposure method for use in the exposure step of the present invention is not particularly limited, so long as at least one of light and heat can be applied to the necessary region of the coated layer obtained from the film forming composition. Examples include, a photo masking method, an electron beam lithography, and the like. Among them, lithography using a beam of electrons is preferred as it enables control of irradiation and irradiation intensity in the fine area.

Exposure conditions in the exposure step are not particularly limited. According to the method used for exposure, exposure area, duration of exposure and exposure intensity and the like can be appropriately selected in order to obtain a desirable pattern.

### [Second Baking Step]

The second baking step is a step in which the cured matter of the film forming composition 2 having the exposed area 3 at least in part is further baked. In the pattern formation method of the present invention, the second baking step is an optional step.

The baking conditions of the second baking step are not particularly limited. For example, the condition can be set under the temperature of no less than 80° C. and no greater than 300° C. for duration of 60 to 300 seconds, and particularly preferably, at no less than 100° C. and no greater than 200° C. for duration of 60 seconds to 180 seconds.

### [Development Step]

FIGS. 1(c1) and 1(c2) show diagrams illustrating the development steps in the pattern formation method according to the first embodiment of the present invention. The development step is a step in which a particular area of the exposed film formed from the film forming composition 2 which has been subjected to the exposure step and to the second baking step as necessary, is removed by dissolving in a developing solution.

FIG. 1(c1) shows a diagram showing a pattern to be provided after the development step when solubility of the exposed area 3 rose higher than the solubility of the non-exposed area 2 upon responding to the exposure in the exposure step. By this development step, the exposed area 3 is removed by dissolving, while the non-exposed area 2 is formed as a pattern.

FIG. 1(c2) shows a diagram illustrating a pattern to be provided after the development step when solubility of the exposed area 3 became lower than solubility of the non-exposed area 2 upon responding to the exposure in the exposure step. By this developing step, the non-exposed area 2 is removed by dissolving, while the exposed area 3 is formed as a pattern.

### Second Embodiment

### Pattern Formation Having the Step-Shaped Lands and Grooves

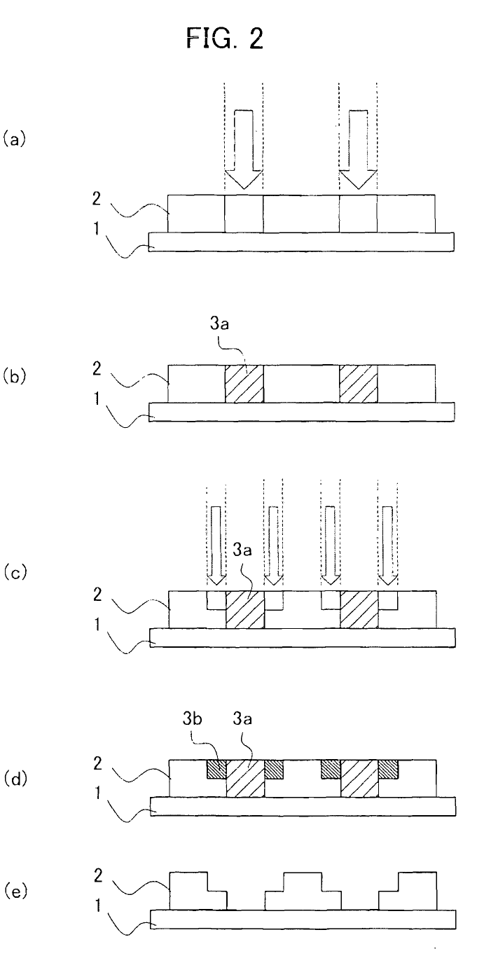

FIG. 2 shows a diagram illustrating a pattern formation method providing the step-shaped lands and grooves according to the second embodiment of the present invention. In the second embodiment, a coating step (not shown in the figure), a first baking step (not shown in the figure), an exposure step (FIGS. 2(a)-(d)), a second baking step (not shown in the figure), and a developing step (FIG. 2(e)) are involved similarly to the first embodiment.

The coating step, first baking step, and second baking step can be performed in a similar manner to those mentioned in the first embodiment. Hereinafter, the exposure step (FIG. 2(a)-(d)) and development step (FIG. 2(e)) in the second embodiment are described.

### [Exposure Step]

In the exposure step of the second embodiment, the first exposure step (FIGS. 2(a)-(b)) and the second exposure step (FIGS. 2(c)-(d)) are included. The first exposure step and second exposure step is a step of performing exposure with different irradiation intensities by controlling the irradiation intensity.

### [First Exposure Step]

In the first exposure step, the cured film of the film forming composition 2 obtained through baking or partially baking in the first baking step is exposed (shown in the figure by an arrow) at least in part to give an exposed film having a first exposed area 3a. In the first exposure step in the second embodiment, irradiation having intensity sufficient to influence up to the deepest portion of the cured film in the depthwise direction of the film forming composition 2 is performed (FIG. 2(a)). Thereby, the first exposed area 3a is formed (FIG. 2(b)) at a level extending to the deepest portion of the cured film of film forming composition 2 (in other words, extending to a portion which contacts with substrate 1).

### [Second Exposure Step]

In the second exposure step, at least a portion of the exposed film regarded as the first exposed area 3a is subjected to a second exposure (shown in the figure by an arrow) to obtain an exposed film having a second exposed area 3b. In the second exposure step of the second embodiment, irradiation having intensity sufficient to influence up to the mid part of the cured film in the depthwise direction (FIG. 2(c)) of the film forming composition 2 is carried out without further influencing up to the deepest portion of the cured film in the depthwise direction. Accordingly, the second exposed area 3b is formed which extends to the mid part of the cured film of the film forming composition 2 (FIG. 2(d)).

### [Development Step]

FIG. 2(e) shows a diagram illustrating the development step in the pattern formation method according to the second embodiment of the present invention.

According to the second embodiment of the present invention, the film forming composition 2 responds to exposure of light, thus solubility thereof in the first exposed area 3a and the second exposed area 3b becomes greater than solubility in the non-exposed area 2. Therefore, in the development step of the second embodiment, the first exposed area 3a and the second exposed area 3b are removed by dissolving, while the non-exposed area 2 is formed as a pattern having the step-shaped lands and grooves (FIG. 2(e)).

### [Film Forming Composition]

The film forming composition of the present invention will be explained below. The film forming composition of the present invention is a composition which includes at least any one of a hydrolyzate or a condensate of an alkoxy metal compound, and a contrast enhancer which enhances the contrast between lands and grooves formed on a film following image development as a result of controlling the solubility of a formed film in a developing solution by responding to at least one of light and heat.

### [Hydrolyzate/condensate of the Alkoxy Metal Compound]

The alkoxy metal compounds which can be used in the present invention are represented by the following formula (A):

R¹ₙ-M(OR²)₄₋ₙ (A)

wherein,

M represents silicon, germanium, titanium, tantalum, indium or stannum;

R¹ represents a hydrogen atom or a monovalent organic group;

R² represents a monovalent organic group; and

n is an integer of 1 to 3.

Here, as the monovalent organic groups, for example, an alkyl group, an aryl group, an allyl group, and a glycidyl group may be exemplified. Among them, preferred are an alkyl group and an aryl group. Especially preferred is the alkyl group having 1 to 5 carbon atoms, such as a methyl, ethyl, propyl and butyl group. Also, the alkyl group may be linear or branched, and may include substitution of hydrogen atom with fluorine atom. As the aryl group, preferred are those having 6 to 20 carbon atoms, such as a phenyl group, a naphthyl group, and the like.

As the metal represented by M having an alkoxy group, silicon is preferably used. In other words, the compound represented by the formula (A) in the present invention is preferably alkoxysilane.

In the alkoxy metal compound represented by the above general formula (A), the alkoxy group is converted into a hydroxy group by hydrolysis to generate an alcohol. Next, two alcohol molecules are condensed to form a network of M-O-M, whereby a coating film is formed.

Specific examples of the compound represented by the above general formula (A) include:

(i) monoalkyltrialkoxy metal compounds such as monomethyltrimethoxy metal compounds, monomethyltriethoxy metal compounds, monomethyltripropoxy metal compounds, monoethyltrimethoxy metal compounds, monoethyltriethoxy metal compounds, monoethyltripropoxy metal compounds, monopropyltrimethoxy metal compounds, and monopropyltriethoxy metal compounds, and monophenyltrialkoxy metal compounds such as monophenyltrimethoxy metal compounds, and monophenyltriethoxy metal compounds, and the like, when n=1;

(ii) dialkyldialkoxy metal compounds such as dimethyldimethoxy metal compounds, dimethyldiethoxy metal compounds, dimethyldipropoxy metal compounds, diethyldimethoxy metal compounds, diethyldiethoxy metal compounds, diethyldipropoxy metal compounds, dipropyldidimethoxy metal compounds, dipropyldiethoxy metal compounds, and dipropyldipropoxy metal compounds, and diphenyldialkoxy metal compounds such as diphenyldimethoxy metal compounds, and diphenyldiethoxy metal compounds, and the like, when n=2; and

(iii) trialkylalkoxy metal compounds such as trimethylmethoxy metal compounds, trimethylethoxy metal compounds, trimethylpropoxy metal compounds, triethylmethoxy metal compounds, triethylethoxy metal compounds, triethylpropoxy metal compounds, tripropylmethoxy metal compounds, and tripropylethoxy metal compounds, and triphenylalkoxy metal compounds such as triphenylmethoxy metal compounds, and triphenylethoxy metal compounds, and the like, when n=3.

Among them, the monomethyltrialkoxy metal compounds such as monomethyltrimethoxy metal compounds, monomethyltriethoxy metal compounds, and monomethyltripropoxy metal compounds may preferably be used.

Also, the alkoxy metal compound as exemplified above may be used in the film forming composition of the present invention alone or in combination.

In the film forming composition of the present invention, the weight average molecular weight of the condensate may preferably be no less than 200 and no greater than 50,000, more preferably no less than 1000 and no greater than 3000 when the condensate of the alkoxy metal compound represented by the formula (A) is included. Using the condensate having the weight average molecular weight falling within this range, the coating properties of the film forming composition can be improved. Also, in the presence of the condensate, adhesion between the substrate and the film formed from the film forming composition can be improved.

The condensation of alkoxy metal compound represented by the formula (A) is obtained by reacting the alkoxy metal compound, as a polymerization monomer, in an organic solvent in the presence of an acid catalyst. With respect to the alkoxy metal compound as a polymerization monomer, it may be used singly or simultaneously in combination to allow for condensation.

As a prerequisite for condensation, the degree of hydrolysis of the alkoxy metal compound can be adjusted by the amount of water added, generally by adding water at 1.0-10.0 times molar ratio, preferably at 1.5-8.0 times molar ratio relative to the total number of moles of the alkoxy metal compound represented by the above formula (A). When the amount of water added is less than 1.0 time mol, the degree of hydrolysis becomes so low that the coating film formation may be difficult. In contrast, the molar ratio exceeding 10.0 times mol is likely to cause the gelation, whereby the storage stability may be inferior.

Also, the acid catalyst used in condensation of the alkoxy metal compound represented by the formula (A), is not particularly limited, and any one of conventionally used organic acids and inorganic acids can be employed. Examples of the organic acid include organic carboxylic acids such as acetic acid, propionic acid and butyric acid, and examples of the inorganic acid include hydrochloric acid, nitric acid, sulfuric acid, phosphoric acid, and the like. The acid catalyst may be directly added to a mixture of the alkoxy metal compound with water, or may be added as an acidic aqueous solution with water which should be added to the alkoxy metal compound.

Hydrolysis reaction is usually completed within 5 to 100 hours. Also, the reaction time required to complete the hydrolysis reaction can be reduced by adding an aqueous acid catalyst solution dropwise to an organic solvent containing at least one alkoxy metal compound represented by the formula (A), under a heating temperature between a room temperature and an elevated temperature not exceeding 80° C. Thus hydrolyzed alkoxy metal compound then causes a condensation reaction, and consequently forms a network of M-O-M.

### [Contrast Enhancer]

The film forming composition of the present invention includes a contrast enhancer which enhances the contrast between lands and grooves formed on a film following image development as a result of controlling the solubility of the formed film in the developing solution by responding to at least one of light and heat. The contrast enhancer of the present invention is not particularly limited as long as the above function is exerted. The contrast enhancer can be appropriately selected from known compounds depending on the type of film forming composition and developing solution used.

With respect to the film forming composition according to the present invention, the content of the contrast enhancer is preferably no less than 0.1% by mass and no greater than 30.0% by mass. When the content of the contrast enhancer is no less than 0.1% by mass, sufficient effect of the contrast enhancer may be exhibited, thereby enabling a pattern to be provided with sufficient contrast after treating in the developing solution. In contrast, when the content of the contrast enhancer is no greater than 30.0% by mass, retention stability of the film forming composition can be improved, and the fall in the amount of film decrement in the unexposed section during image developing can be prevented, deterioration of the contrast can be prevented. The content of the contrast enhancer is more preferably no less than 1.0% by mass and no greater than 15.0% by mass, and still more preferably no less than 5.0% by mass and no greater than 10.0% by mass.

Specific example of the contrast enhancer used in the present invention include photobase generators, thermal base generators, photoacid generators, and thermal acid generators. Among them, a photobase generator can be preferably used.

The photobase generator preferably used in the present invention is a compound which generates a base in response to light. When the film obtained from the film forming composition of the present invention is subjected to an image development process, an acid is often used as a developing solution. When such an acid is used, a base generated in the coated film from the photobase generator upon irradiation of light reacts with the acid in the developing solution, whereby the solubility of the film in the exposed area can be further increased.

Although the photobase generator is not particularly limited, for example, triphenylmethanol; photoactive carbamate such as benzylcarbamate and benzoincarbamate; amide such as o-carbamoylhydroxylamide, o-carbamoyloxime, aromatic sulfonamide, a-lactam and N-(2-allylethynyl)amide, and other amide; oxime esters, a-aminoacetophenone, cobalt complexes and the like, can be included. Among them, preferred can include 2-nitrobenzylcyclohexylcarbamate, triphenylmethanol, o-carbamoylhydroxylamide, o-carbamoyloxime, [[(2,6-dinitrobenzyl)oxy]carbonyl]cyclohexylamine, bis[[(2-nitrobenzyl)oxy]carbonyl]hexane 1,6-diamine, 4-(methylthiobenzoyl)-1-methyl-1-morpholinoethane, (4-morpholinobenzoyl)-1-benzyl-1-dimethylaminopropane, N-(2-nitrobenzyloxycarbonyl)pyrrolidine, hexamminecobalt(III) tris(triphenylmethyl borate), 2-benzyl-2-dimethylamino-1-(4-morpholinophenyl)butanone, and the like.

The thermal base generator used in the present invention is a compound which generates a base in response to heat. Although the thermal base generator is not particularly limited, for example, carbamate derivatives such as 1-methyl-1-(4-biphenylyl)ethylcarbamate, and 1,1-dimethyl-2-cyanoethylcarbamate; urea derivatives such as urea and N,N-dimethyl-N′-methylurea; dihydropyridine derivatives such as 1,4-dihydronicotinamide; quaternized ammonium salts of organosilane and organoborane, dicyandiamide and the like can be used. In addition, examples include guanidine trichloroacetate, methylguanidine trichloroacetate, potassium trichloroacetate, guanidine phenylsulfonylacetate, guanidine p-chlorophenylsulfonylacetate, guanidine p-methanesulphonylphenylsulfonylacetate, potassium phenylpropiolate, guanidine phenylpropiolate, cesium phenylpropiolate, guanidine p-chlorophenylpropiolate, guanidine p-phenylene-bis-phenylpropiolate, tetramethylammonium phenylsulfonylacetate, tetramethylammonium phenylpropiolate, and the like.

The photoacid generator used in the present invention is a compound which generates an acid in response to light. Although the photoacid generator is not particularly limited, for example, known acid generators such as onium salts, diazomethane derivatives, glyoxime derivatives, bissulfone derivatives, β-ketosulfone derivatives, disulfone derivatives, nitrobenzylsulfonate derivatives, sulfonic acid ester derivatives, and sulfonic acid ester derivatives of N-hydroxyimide compounds, and the like, can be used.

Specific examples of the aforementioned onium salt include tetramethylammonium trifluoromethanesulfonate, tetramethylammonium nonafluorobutanesulfonate, tetra-n-butylammonium nonafluorobutanesulfonate, tetraphenylammonium nonafluorobutanesulfonate, tetramethylammonium p-toluenesulfonate, diphenyliodonium trifluoromethanesulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethanesulfonate, bis(p-tert-butoxyphenyl)phenylsulfonium trifluoromethanesulfonate, tris(p-tert-butoxyphenyl)sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl)sulfonium p-toluenesulfonate, triphenylsulfonium nonafluorobutanesulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethanesulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicylcohexylphenylsulfonium trifluoromethanesulfonate, dicyclohexylphenylsulfonium p-toluenesulfonate, trinaphthylsulfonium trifluoromethanesulfonate, cyclohexylmethyl(2-oxocyclohexyl)sulfonium trifluoromethanesulfonate, (2-norbornyl)methyl(2-oxocyclohexyl)sulfonium trifluoromethanesulfonate, ethylenebis[methyl(2-oxocyclopentyl)sulfonium trifluoromethanesulfonate], 1,2′-naphthylcarbonylmethyltetrahydrothiopheniumtriflate, and the like.

Examples of the aforementioned diazomethane derivative include bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, bis(tert-butylsulfonyl)diazomethane, bis(n-amylsulfonyl)diazomethane, bis(isoamylsulfonyl)diazomethane, bis(sec-amylsulfonyl)diazomethane, bis(tert-amylsulfonyl)diazomethane, 1-cyclohexylsulfonyl-1-(tert-butylsulfonyl)diazomethane, 1-cyclohexylsulfonyl-1-(tert-amylsulfonyl)diazomethane, 1-tert-amylsulfonyl-1-(tert-butylsulfonyl)diazomethane, and the like.

Examples of the aforementioned glyoxime derivative include bis-o-(p-toluenesulfonyl)-a-dimethylglyoxime, bis-o-(p-toluenesulfonyl)-a-diphenylglyoxime, bis-o-(p-toluenesulfonyl)-a-dicyclohexylglyoxime, bis-o-(p-toluenesulfonyl)-2,3-pentanedioneglyoxime, bis-o-(p-toluenesulfonyl)-2-methyl-3,4-pentanedioneglyoxime, bis-o-(n-butanesulfonyl)-a-dimethylglyoxime, bis-o-(n-butanesulfonyl)-a-diphenylglyoxime, bis-o-(n-butanesulfonyl)-a-dicyclohexylglyoxime, bis-o-(n-butanesulfonyl)-2,3-pentanedioneglyoxime, bis-o-(n-butanesulfonyl)-2-methyl-3,4-pentanedioneglyoxime, bis-o-(methanesulphonyl)-a-dimethylglyoxime, bis-o-(trifluoromethanesulfonyl)-a-dimethylglyoxime, bis-o-(1,1,1-trifluoroethanesulfonyl)-a-dimethylglyoxime, bis-o-(tert-butanesulfonyl)-a-dimethylglyoxime, bis-o-(perfluorooctanesulfonyl)-a-dimethylglyoxime, bis-o-(cyclohexanesulfonyl)-a-dimethylglyoxime, bis-o-(benzenesulfonyl)-a-dimethylglyoxime, bis-o-(p-fluorobenzenesulfonyl)-a-dimethylglyoxime, bis-o-(p-tert-butylbenzenesulfonyl)-a-dimethylglyoxime, bis-o-(xylenesulfonyl)-a-dimethylglyoxime, bis-o-(camphorsulfonyl)-a-dimethylglyoxime, and the like.

Examples of the aforementioned bissulfone derivative include bisnaphthylsulfonylmethane, bistrifluoromethylsulfonylmethane, bismethylsulfonylmethane, bisethylsulfonylmethane, bispropylsulfonylmethane, bisisopropylsulfonylmethane, bis-p-toluenesulfonylmethane, bisbenzenesulfonylmethane, and the like.

Examples of the aforementioned β-ketosulfone derivative include 2-cyclohexylcarbonyl-2-(p-toluenesulfonyl)propane, 2-isopropylcarbonyl-2-(p-toluenesulfonyl)propane, and the like.

Examples of the disulfone derivative include disulfone derivatives such as diphenyldisulfone derivatives, dicyclohexyldisulfone derivative, and the like.

Examples of the aforementioned nitrobenzylsulfonate derivative include nitrobenzylsulfonate derivatives such as 2,6-dinitrobenzyl p-toluenesulfonate, 2,4-dinitrobenzyl p-toluenesulfonate, and the like.

Examples of the aforementioned sulfonic acid ester derivative include sulfonic acid ester derivatives such as 1,2,3-tris(methanesulfonyloxy)benzene, 1,2,3-tris(trifluoromethanesulfonyloxy)benzene, 1,2,3-tris(p-toluenesulfonyloxy)benzene, and the like.

Examples of the aforementioned sulfonic acid ester derivatives of N-hydroxyimide compounds include N-hydroxysuccinimidemethanesulfonic acid ester, N-hydroxysuccinimidetrifluoromethanesulfonic acid ester, N-hydroxysuccinimideethanesulfonic acid ester, N-hydroxysuccinimide 1-propanesulfonic acid ester, N-hydroxysuccinimide 2-propanesulfonic acid ester, N-hydroxysuccinimide 1-pentanesulfonic acid ester, N-hydroxysuccinimide 1-octanesulfonic acid ester, N-hydroxysuccinimide p-toluenesulfonic acid ester, N-hydroxysuccinimide p-methoxybenzenesulfonic acid ester, N-hydroxysuccinimide 2-chloroethanesulfonic acid ester, N-hydroxysuccinimidebenzenesulfonic acid ester, N-hydroxysuccinimide 2,4,6-trimethylbenzenesulfonic acid ester, N-hydroxysuccinimide 1-naphthalenesulfonic acid ester, N-hydroxysuccinimide 2-naphthalenesulfonic acid ester, N-hydroxy-2-phenylsuccinimidemethanesulfonic acid ester, N-hydroxymaleimidemethanesulfonic acid ester, N-hydroxymaleimideethanesulfonic acid ester, N-hydroxy-2-phenylmaleimidemethanesulfonic acid ester, N-hydroxyglutarimidemethanesulfonic acid ester, N-hydroxyglutarimidebenzenesulfonic acid ester, N-hydroxyphthalimidemethanesulfonic acid ester, N-hydroxyphthalimidebenzenesulfonic acid ester, N-hydroxyphthalimidetrifluoromethanesulfonic acid ester, N-hydroxyphthalimide p-toluenesulfonic acid ester, N-hydroxynaphthalimidemethanesulfonic acid ester, N-hydroxynaphthalimidebenzenesulfonic acid ester, N-hydroxy-5-norbornene-2,3-dicarboxylmidemethanesulfonic acid ester, N-hydroxy-5-norbornene-2,3-dicarboxyimidetrifluoromethanesulfonic acid ester, N-hydroxy-5-norbornene-2,3-dicarboxylmide p-toluenesulfonic acid ester, and the like.

The thermal acid generator used in the present invention is a compound which generates acid in response to heat. Although the thermal acid generator is not particularly limited, for example, commonly used thermal acid generators involving 2,4,4,6-tetrabromocyclohexadienone, benzointosilate, 2-nitrobenzyltosilate, other alkyl esters of organic sulfonic acid, and compositions containing at least one of the foregoing thermal acid generators can be used.

### [Other Components]

### [Solvent]

From the perspective of achieving improved coating properties and uniform film thickness, it is preferable that the film forming composition of the present invention contain a solvent. As the solvent, any organic solvent which has been conventionally used can be employed. Specific example of the solvent include monovalent alcohols such as methyl alcohol, ethyl alcohol, propyl alcohol, butyl alcohol, 3-methoxy-3-methyl-1-butanol, 3-methoxy-1-butanol; alkyl carboxylic esters such as methyl-3-methoxypropionate, and ethyl-3-ethoxypropionate; polyvalent alcohols such as ethylene glycol, diethylene glycol, and propylene glycol; polyvalent alcohol derivatives such as ethylene glycol monomethyl ether, ethylene glycol monoethyl ether, ethylene glycol monopropyl ether, ethylene glycol monobutyl ether, propylene glycol monomethyl ether, propylene glycol monoethyl ether, propylene glycol monopropyl ether, propylene glycol monobutyl ether, ethylene glycol monomethyl ether acetate, ethylene glycol monoethyl ether acetate, propylene glycol monomethyl ether acetate, and propylene glycol monoethyl ether acetate; aliphatic acids such as acetic acid, and propionic acid; ketones such as acetone, methylethylketone, and 2-heptanone. These organic solvents may be used alone, or in combination of two or more.

Although the amount of the solvent is not particularly limited, preferably the concentration of the ingredients other than the solvent (solid content) become 5 to 100% by mass, and more preferably 20 to 50% by mass. By adjusting to fall within the range described above, the coating properties can be improved.

### [Various Additives]

Also, in the present invention, additives such as other resin, a surface activating agent, a coherence supporting agent, and the like can be formulated within a scope not to impair the effects of the present invention. The other component can be freely selected depending on the intended function to be imparted.

When a surface active agent is added, the coating properties of the resultant composition are improved, and the flatness of the resultant film is also improved. Examples of such a surface active agent include, fluorinated surface active agents such as BM-1000 (manufactured by BM Chemie Co., Ltd.), Megafax F142D, F172, F173, and F183 (manufactured by Dainippon Ink and Chemicals, Ltd.), Fluorad FC-135, FC-170C, Fluorad FC-430, and FC-431 (manufactured by Sumitomo 3M Limited), Surflon S-112, S-113, S-131, S-141, and S-145 (manufactured by Asahi Glass Co., Ltd.), SH-28PA, SH-190, SH-193, SZ-6032, SF-8428, DC-57, and DC-190 (manufactured by Dow Corning Toray Silicone Co., Ltd.), and the like. The ratio of the surface active agent, when compounded, is usually no greater than 5 parts by weight, preferably from 0.01 parts by weight to 2 parts by weight per 100 parts by weight of the solid content other than the surface active agent.

Also, adhesiveness to the substrate of the film forming composition is improved by adding an adhesive aid. As the adhesive aid, a silane compound (functional silane coupling agent) having a reactive substituent such as a carboxyl group, methacryloyl group, isocyanate group, epoxy group or the like is preferably used. Specific examples of the functional silane coupling agent include trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, β-(3,4-epoxycyclohexyl)ethyltrimethoxysilane, and the like. The ratio of the adhesive aid, when compounded, is usually no greater than 20 parts by weight, preferably from 0.05 parts by weight to 10 parts, and particularly preferably from 1 part by weight to 10 parts by weight per 100 parts by weight of the solid content other than the adhesive aid.

### [Developing Solution]

The developing solution used for pattern formation of the present invention is not particularly limited. However, there are cases in which the film obtained from the film forming composition of the present invention becomes glassy due to the first baking step. A buffered hydrofluoric acid (BHF) in the form of a solution of a mixture including fluorinated acid and ammonium fluoride is effective to make a glassy material corrode. For this reason, as the developing solution, it is preferable to use the buffered hydrofluoric acid in the present invention.

### [Application of Pattern]

The three-dimensional pattern obtained using the film forming composition of the present invention can be appropriately used in various fields depending on the size and precision of the pattern.

The structural body having a three-dimensional pattern obtained from the film forming composition of the present invention can be preferably used, for example, as a mold for lithography due to high degree of precision in the contrast of provided lands and grooves with or without a step-shape. Especially, when the structural body having step-shaped lands and grooves is used as a mold for lithography, a pattern having step-shaped lands and grooves can be obtained by single transfer.

Especially, the structural body having a three-dimensional pattern obtained from the film forming composition of the present invention is light transparent. Thus, upon irradiation of light using ultraviolet light or the like while having the three-dimensional structural body of the present invention pressed against a resist film, the resist film can be cured using the light which passes through the three-dimensional structural body. Accordingly, it can be preferably used as a mold for photoimprint lithography.

Also, in the exposure step, by finely controlling at least one of the exposed area and the exposure intensity of the light, a nano-scale structure can be provided. The three-dimensional structural body having the nano-scale structure can be preferably used as a mold for nanoimprint lithography.

### EXAMPLES

Next, the present invention will be explained in more detail with reference to Examples; however, the present invention should not be construed as being limited thereto.

### Example 1

367.7 g (2.7 mol) of methyltrimethoxysilane, 411.0 g (2.7 mol) of tetramethoxysilane, 690.5 g of acetone, and 690.5 g of isopropyl alcohol were mixed and stirred. Thereto were added 340.2 g (19.0 mol) of water and 58.9 μL of 60% by mass nitric acid, and the mixture was stirred for additional 3 hours to allow a hydrolysis reaction. In this reaction, the rate of hydrolysis was about 200%.

Subsequently, the hydrolysis reaction was allowed at 26° C. for 2 days, and a reaction solution including a siloxane polymer was obtained. The mass average molecular weight (Mw) of the siloxane polymer in the reaction solution was 1956.

Thus resulting reaction solution was adjusted with a mixture of acetone:isopropyl alcohol=1:1 so as to give the Si equivalent mass % of 7% by mass. Furthermore, 51.4 g (0.189 mol) of a photobase generator (NBC-101, manufactured by Midori Kagaku Corporation) represented by the following formula (B) was added to the adjusted solution. Accordingly, a film forming composition was obtained.

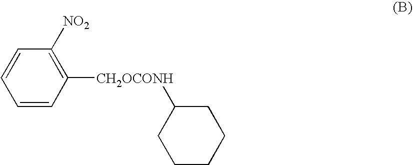

The above obtained film forming composition was applied onto a silicon wafer by a spin coating method to form a film having a thickness of 2,600 Å, and baked at 300° C. for 90 seconds to obtain a cured film.

Thus obtained cured film was subjected to electron beam lithography using an electron beam lithography system (HL-800D manufactured by Hitachi Ltd., 70 kV acceleration voltage) to form a pattern with 200 nm line and space. Thereafter, image development was performed with BHF (HF/NH₄F=70/30, photographic density: 2.5%), followed by washing with water. Accordingly, it was confirmed that a three-dimensional mold of 200 nm line and space was obtained.

### INDUSTRIAL APPLICABILITY

The three-dimensional pattern obtained according to the present invention can be appropriately used in various fields depending on the size and degree of precision of the formed pattern. Especially, it can be advantageously used in the formation of a mold for nanoimprint lithography when the pattern is formed to have a fine structure in the order of nanometer.

1. A film forming composition, comprising:
at least one of a hydrolyzate and a concentrate of an alkoxy metal compound represented by the following formula (A); and
a contrast enhancer which enhances the contrast between lands and grooves formed on a film following image development as a result of controlling the solubility of the formed film in a developing solution by responding to at least one of light and heat
R¹ₙ-M(OR²)₄₋ₙ (A)
wherein,
M represents silicon, germanium, titanium, tantalum, indium or stannum;
R¹ represents a hydrogen atom or a monovalent organic group;
R² represents a monovalent organic group; and
n is an integer of 1 to 3.

2. The film forming composition according to claim 1, wherein the content of the contrast enhancer is no less than 0.1% by mass and no greater than 30.0% by mass of the total mass of the film forming composition.

3. The film forming composition according to claim 1, wherein the contrast enhancer is a photobase generator.

4. The film forming composition according to claim 1 used for forming a three-dimensional mold.

5. A three-dimensional mold obtained by exposing light to a coating film obtained from the film forming composition according to claim 1, followed by development.

6. The three-dimensional mold according to claim 5, further comprising step-shaped lands and grooves constructed with a plurality of combined lands and grooves obtained by performing sequential exposure of irradiation at a controlled intensity.

7. Use of the three-dimensional mold according to claim 5 for lithography.

8. A pattern formation method using lithography, comprising:
a coating step for obtaining a coating layer by applying the film forming composition of claim 1;
a first baking step for forming a cured film by baking or partially baking the coating layer;
an exposure step for obtaining an exposed film in at least a portion of the cured film exposed to light as an exposed area; and
a developing step for treating the exposed film in a developing solution and selectively dissolving either the exposed area or a non-exposed area other than the exposed area.

9. The pattern formation method according to claim 8 further comprising a second baking step for baking the exposed film after the exposure step.

10. The pattern formation method according to claim 8, wherein the exposure step is electron beam lithography.

11. The pattern formation method according to claim 8, wherein the developing solution is a buffered hydrofluoric acid.

12. The pattern formation method according to claim 8, which is a nano-pattern formation method.

13. A three-dimensional structural body obtained by the pattern formation method according to claim 8.

14. The three-dimensional structural body according to claim 13 comprising step-shaped lands and grooves formed by combining a plurality of lands and grooves.

15. The three-dimensional structural body according to claim 13, which is a nano-structural body.

16. The three-dimensional structural body according to claim 13, which is a mold for lithography.

17. The three-dimensional structural body according to claim 13, which is a mold for nanoimprint lithography.
